(19) United States
(12) Patent Application Publication
(10) Pub. No.: US 2006/0061957 A1
(43) Pub. Date: Mar. 23, 2006

(54) Multi-disk based data storage unit and tape emulation system for offsite data backup

(76) Inventors: Yung Yip, Afton, MN (US); James R. Kramlich, Oakdale, MN (US)

Correspondence Address: Attention: Eric D. Levinson;Imation Corp., Legal Affairs, P.O. Box 64898, St. Paul, MN, 55164-0898, US

(21) Appl. No.: 11/219,045

(22) Filed: Sep. 2, 2005

Related U.S. Application Data
(60) Provisional application No. 60/611,970, filed on Sep. 22, 2004.

(51) Int. Cl. H05K 5/00

(52) U.S. Cl. 361/685

(57) ABSTRACT

The invention contemplates a disk based data storage unit. The storage unit includes a plurality of disk drives all within a self-contained unit. The data storage unit may resemble a suitcase and may be ruggedized. The data storage unit may include a handle and possibly wheels to simplify transport of the data storage unit. The data storage unit can replace a plurality of tape cartridges or disk cartridges. A user backs up data onto the storage unit and then moves the storage unit off-site. The suitcase-like form factor and suitcase transporting features allow for easy transport of a large volume of data. Emulation may be used to facilitate communication between the data storage unit and a host computer executing data storage tape software commonly used in data backup and archive applications.

### CROSS-REFERENCE TO RELATED APPLICATION

The subject matter of this application is related to the subject matter of U.S. Provisional Patent Application No. 60/611,970, filed Sep. 22, 2004, priority to which is claimed under 35 U.S.C. § 119(e) and which is incorporated herein by reference.

### TECHNICAL FIELD

The invention relates to data storage devices.

### SUMMARY

In general, the invention is directed to a disk-based data storage unit. The storage unit includes a plurality of disk drives within a self-contained unit. The data storage unit may resemble a suitcase, including a handle and possibly including wheels. The data storage unit can replace a plurality of tape cartridges or disk cartridges. A user backs up data onto the storage unit and then moves the storage unit off-site.

In one embodiment, the invention provides a data storage unit comprising a housing defining a suitcase-like form factor, a plurality of disk drives within the housing, and an interface accessible through the housing to enable data transfer to and from the disk drives.

In another embodiment, the invention provides a system comprising a data storage unit comprising a plurality of disk drives and an interface to enable data transfer to and from the disk drives, a host computer comprising data storage software that conforms to a data storage tape protocol, and an emulator to present the disk drives to the host computer as one or more tape drives and to transfer data to the disk drives according to a disk drive communication protocol.

The details of one or more embodiments of the invention are set forth in the accompanying drawings and the description below. Other features, objects, and advantages of the invention will be apparent from the description and drawings, and from the claims.

### BRIEF DESCRIPTION OF DRAWINGS

FIG. 1 is a block diagram of a data storage unit according to an embodiment of the invention.

FIG. 2 is a block diagram of a system comprising a data storage unit, a host computer and an emulator according to an embodiment of the invention.

FIGS. 3 and 4 are block diagrams of data storage units that can communicatively couple to docking station emulators.

### DETAILED DESCRIPTION

The invention contemplates a disk-based data storage unit. The storage unit includes a plurality of disk drives all within a self-contained unit. The data storage unit may resemble a suitcase and may be ruggedized. The data storage unit may include a handle and possibly wheels to simplify transport of the data storage unit. The data storage unit can replace a plurality of tape cartridges or disk cartridges. A user backs up data onto the storage unit and then moves the storage unit off-site. The suitcase-like form factor and suitcase transporting features such as handles and wheels allow for easy transport of a large volume of data.

The disk drives in the storage unit may be arranged to define one or more input data paths, and may define a RAID architecture. RAID stands for “Redundant Array of Independent Disks.” The primarily contemplated use of the invention is routine off-site storage of disaster recovery data sets, although other uses are also contemplated. Emulation may be used to facilitate communication between the data storage unit and a host computer executing data storage tape software commonly used in data backup and data archive applications.

The data storage unit can provide protection of data storage disks from abusive handling, e.g., with a rugged housing and suitable cushioning or shock-absorbing elements for the hard drives within the housing. Moreover, as mentioned, an emulator may be used with the data storage unit to enable emulation of multiple tape volumes using the RAID architecture. An emulator can provide improved data transfer rates compared to tape drives, yet allow for legacy data backup software that was designed for data storage tape to be used with emulation software. In accordance with the invention, multiple terabytes of data can be transported in a unified storage container, eliminating the handling, storage, and loading of discrete cartridges

Mid-range data centers typically rely on off-site storage of critical data for disaster recovery (DR) operations. A typical routine is to move a full weekly back up of all data sets and store it off-site for temporary safekeeping. The storage media is then recycled through this operation after a period, typically about 4 weeks long. Currently, magnetic tape is the dominant medium for such applications.

The most basic embodiment of this invention is a set of hard disk drives contained in a ruggedized and portable container (referred to as a data storage unit). The disk drives are contained such that the necessary electrical power and data I/O interfaces to an external docking station can be provided. For example, the data storage unit may include a power and data interface to supply the necessary electrical power through the housing of the unit to the disk drives and provide data I/O interfaces to an external docking station. Accordingly, instead of manual loading/unloading of individual tapes for off-site storage, the entire container of disks can be undocked and transported. With current disk drive technology, up to 6 terabytes (TB) of storage capacity can be contained within a briefcase-size container. The form factor of the data storage unit may be approximately 0.15 meters high by 0.5 meters long by 0.3 meters wide. These dimensions may be modified, however, typically by up to +/−0.3 meters in any dimension, while still defining a suitcase-like form factor. More specifically, the data storage unit may define a form factor that conforms to conventional server racks, e.g., defining an approximately 19 inch width corresponding to the width of units received by the server rack. In that case the height may be approximately 4 inches and the depth may be approximately 24-36 inches. Importantly, the dimensions allow the data storage unit to be received on the server rack like any other modular unit.

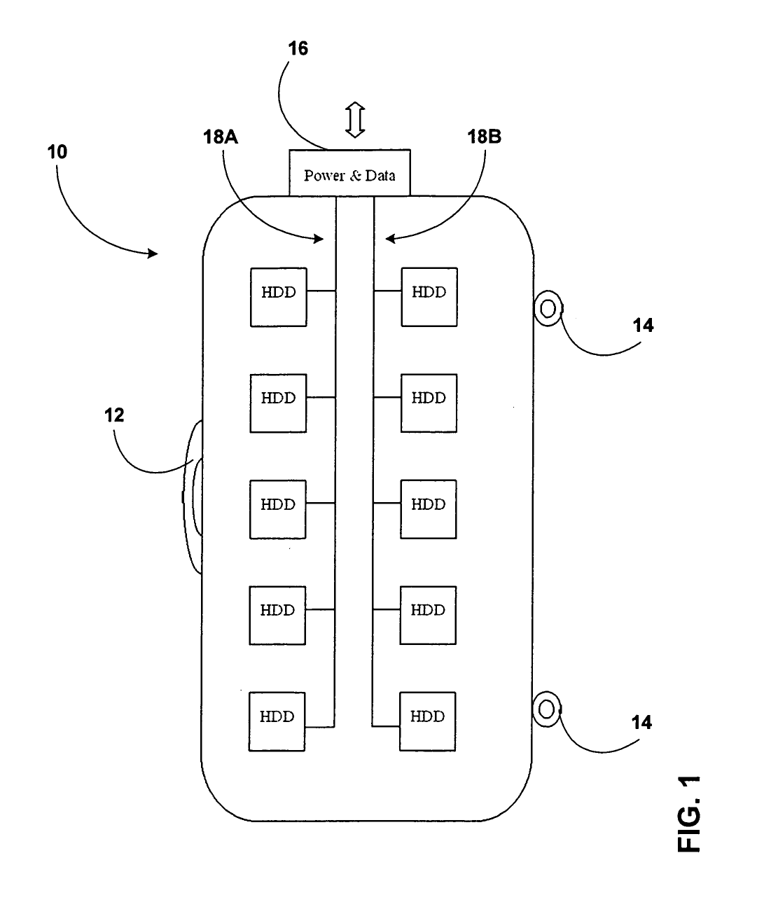

FIG. 1 is a block diagram of an exemplary data storage unit 10 according to an embodiment of the invention. As shown, data storage unit 10 includes a housing that defines a suitcase-like form factor. Data storage unit 10 may also include one or more handles 12 and wheels 14 to simplify transport of unit 10. Housed within storage unit 10 are a plurality of hard disk drives (HDD's). One or more interfaces 16 provide access to the HDDs and provide a means to supply the necessary electrical power to the HDDs and provide data input/output (I/O) interfaces to an external docking station.

Data storage unit 10 may further include shock-absorbing elements (not shown) for improving the shock and vibration protection of the HDDs. Elements for cooling the HDDs (not shown), such as ventilation fans or fluid coolant coils, can also be included within data storage unit 10. Moreover, circuitry for power management (not shown) may also be included in the data storage unit 10.

The HDDs can be configured as one or more RAID arrays for redundancy and speed. The HDDs may also be arranged to define a plurality of data paths. In the illustrated example, two data paths 18A and 18B are illustrated although any number could be defined depending on the data transfer speeds needed for a given application. The HDDs of each of data paths 18A and 18B may be referred to as a RAID set. Each RAID set can facilitate greater than 150 megabytes (MBs) per second of uncompressed data transfer. Thus, unit 10 may define two independent RAID sets to collectively sustain 300 MB/sec or greater. The RAID interface can be contained within data storage unit 10, or as part of a docking station that communicates with unit 10. If desired, a locking mechanism (not shown) may be included to lock interfaces 16 and thereby prevent unauthorized entry or access to the data on HDDs.

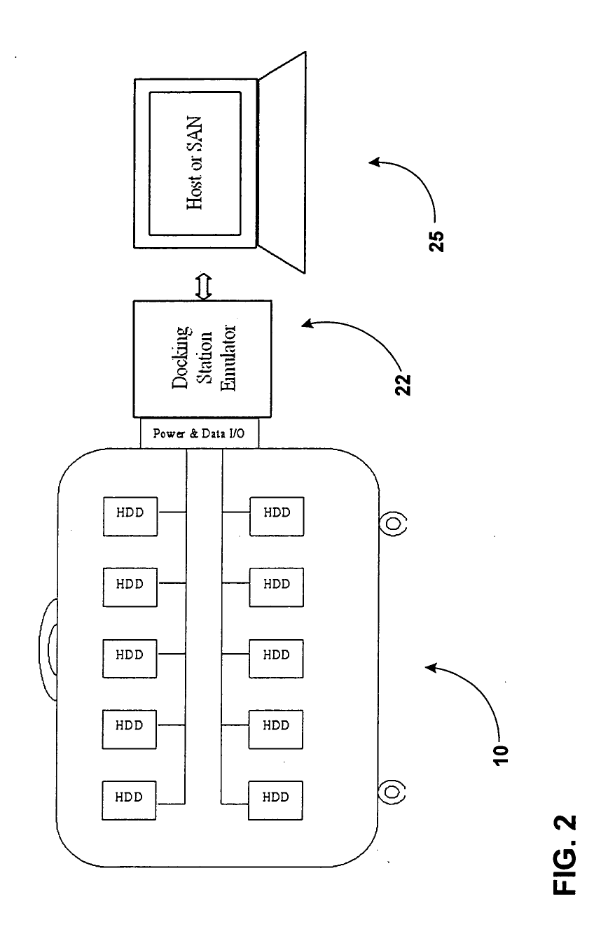

In another embodiment, as shown in FIG. 2, the invention comprises a system that includes a docking station emulator 22 and the data storage unit 10 having a set of hard disk drives. The docking station emulator 22 provides a linking mechanism between data storage unit 10 and a host computer 25. In general, the system includes a data storage unit 10 comprising a plurality of disk drives and an interface to enable data transfer to and from the disk drives, a host computer 25 comprising data storage software that conforms to a data storage tape protocol, and an emulator 22 to present the disk drives to host computer 25 as one or more tape drives and to transfer data to the disk drives according to a disk drive communication protocol.

The docking station/host interface can be Ultra wide SCSI or Fibre Channel. The docking station emulator 22 may also include actuators (not shown) that lock data storage unit 10 into place to prevent removal during data I/O operations. The docking station emulator 22 monitors and reports on status of disk drives within unit 10, and notifies the administrator of host computer 25 when a failure of disk drives is pending.

Docking station emulator 22 generally provides emulation capabilities to emulate communication with one or more tape drives. One or more independent HDDs of the data storage unit 10 would appear to host computer 25 as one or more tape cartridges. If data storage unit 10 contains two independent data paths comprising one or more HDDs, the docking station emulator 22 would typically emulate two independent data paths as being two different data storage tape cartridges supported by host computer 25. Host computer 25 can output tape storage signals, which emulator 22 converts to RAID signals. The RAID signals can then be sent to the HDDs via the data paths to allow for very fast data storage. Data compression hardware can also reside within the docking station/emulator.

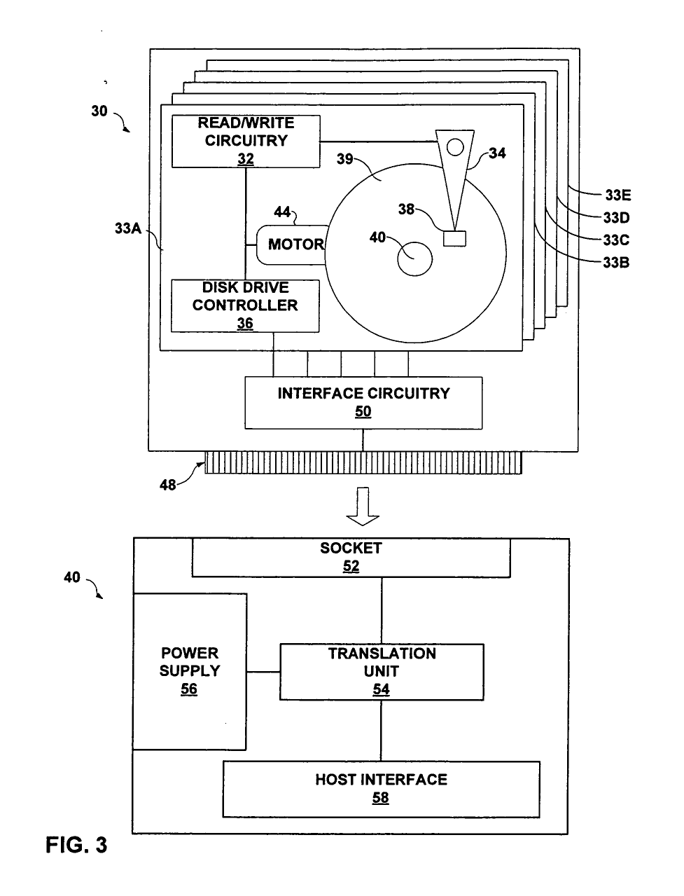

FIG. 3 is a block diagram illustrating a data storage unit 30 coupled to a tape drive emulator 40, which may correspond to a docking station. In this embodiment, data storage unit 30 includes a plurality of disk drives 33A-33E (collectively disk drives 33), each coupled to interface circuitry 50. Physical interface 48 allows data storage unit 30 to be coupled to socket 52 of emulator 40 to enable emulated communication between a host computing device (not shown) and disk drives 33.

In this embodiment, each of disk drives 33 includes a disk drive controller 36 that controls read/write circuitry 32 and actuator 34 to output signals to, and senses signals from, transducer 38. Motor 44 spins hard disk 39 about spindle 37. Disk drive controller 36 communicates with emulator 40 via interface circuitry 50 and electrical interface 48 which couples to socket 52. Interface circuitry 50 may implement a non-conventional communications protocol, or may implement any standard interface protocol, such as the Small Computer System Interface (SCSI), the Fibre Channel interface, the Enhanced Integrated Drive Electronics/AT Attachment (EIDE/ATA) interface, or the like.

Physical interface 48 provides an externally available electrical interface for coupling to tape drive emulator 40 upon insertion of interface 48 into socket 52. In particular, physical interface 48 comprises an electrical connector that provides input/output electrical pins for communicating with, and receiving power from, tape drive emulator 40. Again, data storage unit 30 includes a plurality of disk drives 33 which may be arranged to define one or a plurality of data paths for read/write operations in accordance with a RAID architecture.

Tape drive emulator 40 communicates with a host-computing device (not shown) as conventional tape drives. For example, in response to a query from a host-computing device, tape drive emulator 40 may identify disk drives 33 as one or more conventional tape drives, such as a standard 3480 tape drive. Consequently, the drivers and other software applications executing on the host computing device for accessing tape-based data cartridges need not be modified.

Tape drive emulator 40 may be physically configured for use with conventional backup infrastructure. Unlike conventional systems in which the drives must be upgraded to support larger capacity magnetic tape data cartridges, the tape drive emulators can readily support non-tape data cartridges having increased storage capacities. For example, the tape drive emulators may readily detect the storage capacity data storage unit 30 having non-tape storage media therein, possibly by querying the individual drives 33, and reporting the storage capacity to the host computing device attached to host interface 50.

Tape drive emulator 40 includes socket 52 to make a robust electrical connection to physical interface 48 of data storage unit 30. In one embodiment, socket 52 may comprise a zero insertion force (ZIF) socket. Host interface 58 provides an electrical interface between tape drive emulator 40 and a host computing device (not shown). Host interface 58 may conform to any one of a number of standard communication interfaces such as the Small Computer System Interface (SCSI), the Fibre Channel interface, the Network Data Management Protocol (NDMP), the Enhanced Integrated Drive Electronics/AT Attachment (EIDE/ATA) interface, or the like.

Tape drive emulator 40 may include a translation unit 54 for translating commands received from host interface 58 prior to delivering the commands to data storage unit 30 via socket 52. For example, translation unit 54 may receive data stream commands from host interface 58 that are typical for sequential access devices, such as tape drives, and may translate the stream commands into block commands that are more typical for disk drives or other storage devices. In addition, translation unit 54 may provide data buffering, compression and decompression, data reformatting, error detection and correction, and the like, in order to provide a tape drive interface to the host computer and a non-tape interface to the data storage unit 30. In this manner, tape drive emulator 40 allows data storage unit carrying a plurality of disk drives to appear to the host computing device as one or more sequential storage devices, such as magnetic tape cartridges.

Furthermore, translation unit 54 allows host interface 58 and physical interface 48 of data storage unit 30 to conform to different interface specifications. For example, translation unit 54 may support a SCSI interface between tape drive emulator 40 and the host computer device, and an EIDE interface between tape drive emulator 40 and data storage unit 30. Translation unit 54 may comprise one or more custom application-specific integrated circuits. Alternatively, translation unit 54 could be implemented as a single board computer or software executing on a general purpose microprocessor executing, e.g., on a Unix operating system. Power supply 56 is included in emulator 40 to provide power to emulator and to deliver power from emulator 40 to drives 33 of data storage unit 30.

Tape drive emulator 40 may also incorporate a RAID controller, in accordance with the invention. The RAID controller, for example, may be incorporated within translation unit 54.

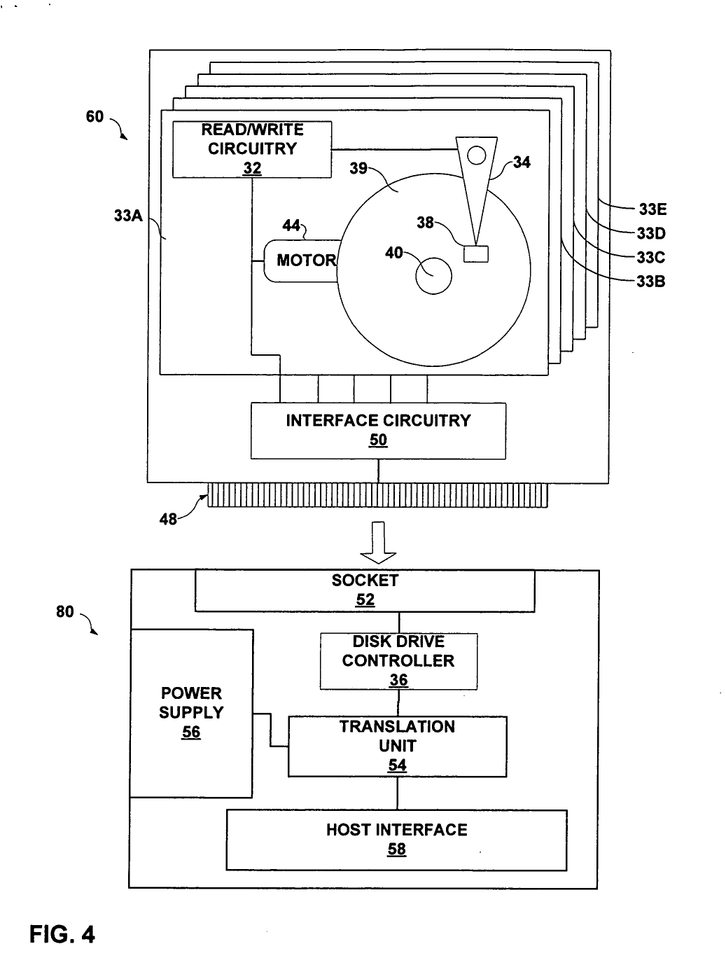

FIG. 4 is another block diagram illustrating a data storage unit 60 coupled to a tape drive emulator 80, which may correspond to a docking station. The system of FIG. 4 operates in a manner substantially similar to the system of FIG. 3. However, in FIG. 4, disk drive controller 36 is included in emulator 80 rather than being included with disk drives 33 as shown in FIG. 3. This may further simplify data storage unit 60, which is transported for data storage backup applications as described herein. Tape drive emulator 80 may also incorporate a RAID controller, in accordance with the invention. In this case, the RAID controller may be incorporated within translation unit 54 or within disk drive controller 36.

Various embodiments of the invention have been described. Nevertheless, it is understood that various modifications can be made without departing from the spirit and scope of the invention. For example, in an added embodiment, other non-tape media such as optical media, Flash or other non-volatile memory, or holographic media may be used in the data storage unit instead of hard drives. In that case, emulation would still enable the host computer to communicate via legacy protocols traditionally used for magnetic tape storage. These and other embodiments are within the scope of the following claims.

1. A data storage unit comprising:
a housing defining a suitcase-like form factor;
a plurality of disk drives within the housing; and
an interface accessible through the housing to enable data transfer to and from the disk drives.

2. The data storage unit of claim 1, wherein the housing includes a handle.

3. The data storage unit of claim 1, wherein the housing includes wheels arranged to simplify transport of the data storage unit.

4. The data storage unit of claim 1, wherein the plurality of disk drives are arranged to define a RAID architecture.

5. The data storage unit of claim 1, wherein the plurality of disk drives are arranged to define a plurality of data paths.

6. A system comprising:
a data storage unit comprising a plurality of disk drives and an interface to enable data transfer to and from the disk drives;
a host computer comprising data storage software that conforms to a data storage tape protocol; and
an emulator to present the disk drives to the host computer as one or more tape drives and to transfer data to the disk drives according to a disk drive communication protocol.
